(19) United States
(12) Patent Application Publication
(10) Pub. No.: US 2023/0234588 A1
(43) Pub. Date: Jul. 27, 2023

(54) VEHICLE

(71) Applicant: HONDA MOTOR CO., LTD., Tokyo (JP)

(72) Inventors: Masashi BANDO, Tokyo (JP); Takahiro KOZEKI, Tokyo (JP)

(73) Assignee: HONDA MOTOR CO., LTD., Tokyo (JP)

(21) Appl. No.: 18/101,330

(22) Filed: Jan. 25, 2023

(30) Foreign Application Priority Data
Jan. 26, 2022 (JP) 2022-010117

(51) Int. Cl. B60W 30/18; B60W 20/00; B60K 11/02

(52) U.S. Cl. CPC B60W 30/18027; B60W 20/00; B60K 11/02; B60W 2710/088; B60W 2510/087; B60W 2540/10; B60W 2540/12; B60W 2710/06

(57) ABSTRACT

A vehicle for activating launch control in response to establishment of a predetermined activation condition includes an electric power conversion device configured to control electric power supplied to an electric motor, the electric motor configured to drive a driven wheel according to electric power supplied via the electric power conversion device, a temperature control circuit in which a temperature control medium circulates to control a temperature of the electric power conversion device, and a control device. The temperature control circuit includes a pump configured to pump the temperature control medium. The control device is configured to control the pump, and when the activation condition is established, the control device is configured to control the pump such that a flow rate of the pump is high as compared with a case where the activation condition is not established.

### CROSS-REFERENCE TO RELATED APPLICATIONS

This application is based on and claims priority under 35 USC 119 from Japanese Patent Application No. 2022-010117 filed on Jan. 26, 2022.

### TECHNICAL FIELD

The present disclosure relates to a vehicle.

### BACKGROUND ART

In recent years, as a specific measure against global climate change, efforts for implementing a low-carbon society or a decarbonized society have become active. Also in a vehicle such as an automobile, a reduction in a CO₂ emission amount and improvement in energy efficiency are required, and electrification of a driving source is in rapid progress. Specifically, a vehicle (hereinafter, also referred to as an “electric vehicle”) including a power supply such as a battery or a generator, an electric motor serving as a driving source, and an electric power conversion device which controls electric power supplied from the power supply to the electric motor, such as an electric automobile or a hybrid electric automobile, has been developed.

There is also a vehicle having a function referred to as “launch control” in which various controls for rapidly starting a stopped vehicle are executed (see, for example, JP-A-2020-076482 described below).

In the electric vehicle using the electric motor as the driving source, when the launch control is activated, a heat generation amount of the electric power conversion device increases, and the electric power conversion device is likely to have a high temperature. When the electric power conversion device has the high temperature, the electric power conversion device may be broken, so that it is necessary to appropriately cool the electric power conversion device. However, in the related art, there is room for improvement from a viewpoint of appropriately cooling the electric power conversion device which is likely to generate heat due to the activation of the launch control.

### SUMMARY

The present disclosure provides a vehicle which can appropriately cool an electric power conversion device which is likely to generate heat due to activation of launch control.

According to an aspect of the present disclosure, there is provided a vehicle for activating launch control in response to establishment of a predetermined activation condition, the vehicle including: an electric power conversion device configured to control electric power supplied to an electric motor; the electric motor configured to drive a driven wheel according to electric power supplied via the electric power conversion device; a temperature control circuit in which a temperature control medium circulates to control a temperature of the electric power conversion device; and a control device, in which: the temperature control circuit includes a pump configured to pump the temperature control medium; and the control device is configured to control the pump, and when the activation condition is established, the control device is configured to control the pump such that a flow rate of the pump is high as compared with a case where the activation condition is not established.

According to the present disclosure, it is possible to provide a vehicle which can appropriately cool an electric power conversion device which is likely to generate heat due to activation of launch control.

### BRIEF DESCRIPTION OF DRAWINGS

FIG. 1 is a diagram illustrating an example of a schematic configuration of a vehicle V according to a first embodiment.

FIG. 2 is a diagram illustrating an example of time changes in temperatures of an electric motor 20 and an electric power conversion device 50.

FIG. 3 is a table illustrating an example of a flow rate of a second pump 621 and a state of a valve device 626 in periods Ta, Tb, and Tc illustrated in FIG. 2.

FIG. 4 is a flowchart illustrating an example of a process executed by a control device ECU according to the first embodiment.

FIG. 5 is a diagram illustrating an example of a schematic configuration of a vehicle V according to a second embodiment.

FIG. 6 is a flowchart illustrating an example of a process executed by a control device ECU according to the second embodiment.

### DESCRIPTION OF EMBODIMENTS

Hereinafter, each embodiment as an example of a vehicle of the present disclosure will be described with reference to the accompanying drawings. The drawings are to be viewed according to directions of reference signs. Further, in the following description, the same or similar elements are denoted by the same or similar reference signs, and description thereof may be omitted or simplified as appropriate.

### First Embodiment

First, a first embodiment of the present disclosure will be described. A vehicle V of the present embodiment is, for example, an electric vehicle of a type referred to as a so-called “sports car”, and is configured to activate launch control in response to establishment of a predetermined activation condition. The activation condition of the launch control is, for example, an operation of simultaneously depressing an accelerator pedal and a brake pedal of the vehicle V. Accordingly, the vehicle V can activate the launch control according to an operation from a user (specifically, a driver) of the vehicle V, that is, a request from the user, and can avoid the launch control from being activated against an intention of the user.

### Vehicle According to First Embodiment

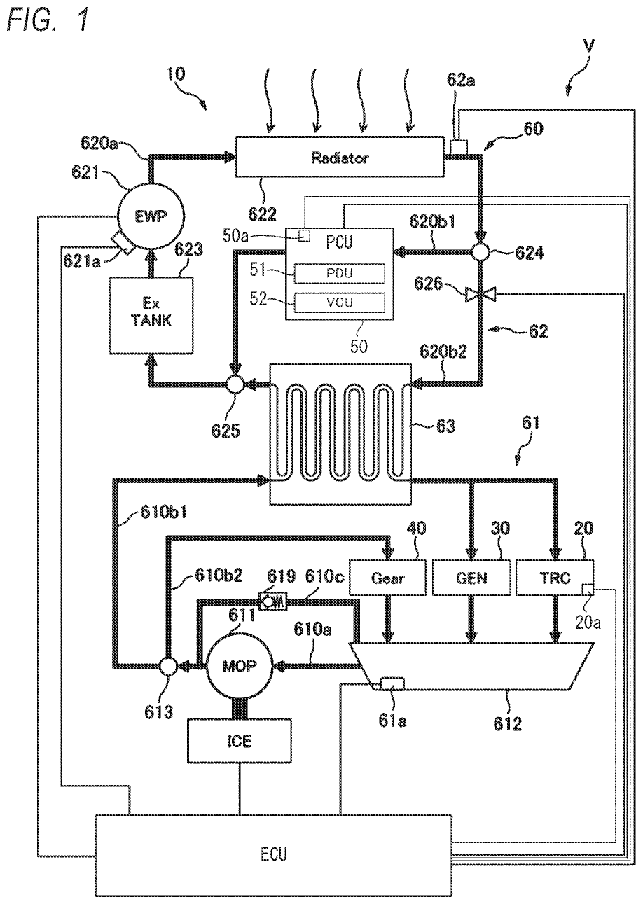

As illustrated in FIG. 1, the vehicle V of the present embodiment includes an internal combustion engine ICE, a control device ECU, a vehicle temperature control system 10, an electric motor 20, a generator 30, a transmission device 40, an electric power conversion device (PCU: power control unit) 50, and a temperature control circuit 60.

The electric motor 20 is a rotary electric machine which outputs power for driving the vehicle V by electric power stored in an electric power storage device (not illustrated) mounted on the vehicle V, or electric power generated by the generator 30. Further, during braking of the vehicle V, the electric motor 20 may generate electric power by kinetic energy of driven wheels of the vehicle V, and may charge the electric power storage device. For example, a three-phase alternating-current motor can be adopted as the electric motor 20. Further, a third temperature sensor 20a which detects a temperature of the electric motor 20 is provided in the electric motor 20. The third temperature sensor 20a outputs a detection value of the temperature of the electric motor 20 to the control device ECU. Accordingly, the control device ECU can acquire the temperature of the electric motor 20.

The generator 30 is a rotary electric machine which generates electric power by power of the internal combustion engine ICE, charges the electric power storage device, or supplies the electric power to the electric motor 20. Similar to the electric motor 20, for example, a three-phase alternating-current motor can be adopted as the generator 30.

The transmission device 40 is a power transmission device provided between the electric motor 20 and the driven wheels of the vehicle V. and configured to perform power transmission between the electric motor 20 and the driven wheels. For example, the transmission device 40 is a gear-type power transmission device which reduces the power output from the electric motor 20 and transmits the reduced power to the driven wheels.

The electric power conversion device 50 includes a power drive unit (PDU) 51 which converts the electric power output from the electric power storage device from direct-current electric power to alternating-current electric power and controls input and output electric power of the electric motor 20 and the generator 30, and a voltage control unit (VCU) 52 which boosts a voltage of the electric power output from the electric power storage device when necessary. The PDU 51 is, for example, an inverter which can convert a direct current into an alternating current (for example, a three-phase alternating current). Further, the VCU 52 is, for example, a DC/DC converter. A fourth temperature sensor 50a which detects a temperature of the electric power conversion device 50 is provided in the electric power conversion device 50. The fourth temperature sensor 50a outputs a detection value of the temperature of the electric power conversion device 50 to the control device ECU. Accordingly, the control device ECU can acquire the temperature of the electric power conversion device 50.

The temperature control circuit 60 includes a first temperature control circuit 61, a second temperature control circuit 62, and a heat exchanger 63. A non-conductive first temperature control medium TCM1 of the first temperature control circuit 61 circulates, and the first temperature control circuit 61 controls temperatures of the electric motor 20, the generator 30, and the transmission device 40. A conductive second temperature control medium TCM2 of the second temperature control circuit 62 circulates, and the second temperature control circuit 62 controls the temperature of the electric power conversion device 50. The heat exchanger 63 performs heat exchange between the first temperature control medium TCM1 which circulates in the first temperature control circuit 61 and the second temperature control medium TCM2 which circulates in the second temperature control circuit 62.

The non-conductive first temperature control medium TCM1 is, for example, oil which is referred to as an automatic transmission fluid (ATF), and which can perform lubrication and the temperature control of the electric motor 20, the generator 30, and the transmission device 40. The conductive second temperature control medium TCM2 is, for example, cooling water referred to as a long life coolant (LLC).

A first pump 611 and a storage portion 612 are provided in the first temperature control circuit 61. The first pump 611 is a mechanical pump which is driven by the power of the internal combustion engine ICE and a rotational force of a vehicle shaft (not illustrated) of the vehicle V. and which pumps the first temperature control medium TCM1. The storage portion 612 stores the first temperature control medium TCM1 which circulates in the first temperature control circuit 61. The storage portion 612 is, for example, an oil pan provided at a bottom portion of a housing (not illustrated) which houses the electric motor 20, the generator 30, and the transmission device 40.

Further, the first temperature control circuit 61 includes a pumping flow path 610a provided with the first pump 611, a first branch flow path 610b1 provided with the electric motor 20 and the generator 30, a second branch flow path 610b2 provided with the transmission device 40, and a branch portion 613 which branches into the first branch flow path 610b1 or the second branch flow path 610b2.

An upstream end portion of the pumping flow path 610a is connected to the storage portion 612, and a downstream end portion of the pumping flow path 610a is connected to the branch portion 613 through the first pump 611. An upstream end portion of the first branch flow path 610b1 is connected to the branch portion 613, and a downstream end portion of the first branch flow path 610b1 is connected to the storage portion 612 through the electric motor 20 and the generator 30. An upstream end portion of the second branch flow path 610b2 is connected to the branch portion 613, and a downstream end portion of the second branch flow path 610b2 is connected to the storage portion 612 through the transmission device 40.

In the first temperature control circuit 61, the heat exchanger 63 is disposed upstream of the electric motor 20 and the generator 30 of the first branch flow path 610b1. Therefore, in the first temperature control circuit 61, a first flow path in which the first temperature control medium TCM1 pumped from the first pump 611 passes through the first branch flow path 610b1 from the branch portion 613, is cooled by exchanging heat with the second temperature control medium TCM2 in the heat exchanger 63, is supplied to the electric motor 20 and the generator 30 to perform the lubrication and the temperature control of the electric motor 20 and the generator 30, and then is stored in the storage portion 612, and a second flow path in which the first temperature control medium TCM1 pumped from the first pump 611 passes through the second branch flow path 610b2 from the branch portion 613, is supplied to the transmission device 40 to perform the lubrication and the temperature control of the transmission device 40, and then is stored in the storage portion 612 are formed in parallel, and the first temperature control medium TCM1 stored in the storage portion 612 flows through the pumping flow path 610a to be supplied to the first pump 611, and the first temperature control medium TCM1 circulates in the first temperature control circuit 61.

In the present embodiment, the first branch flow path 610b1 and the second branch flow path 610b2 are formed such that a flow rate of the first temperature control medium TCM1 which flows through the first branch flow path 610b1 is higher than a flow rate of the first temperature control medium TCM1 which flows through the second branch flow path 610b2.

A first temperature sensor 61a which detects a temperature of the first temperature control medium TCM1 which circulates in the first temperature control circuit 61 is provided in the first temperature control circuit 61. In the present embodiment, the first temperature sensor 61a is provided in the storage portion 612 which is the oil pan, and detects the temperature of the first temperature control medium TCM1 stored in the storage portion 612. The first temperature sensor 61a outputs a detection value of the temperature of the first temperature control medium TCM1 stored in the storage portion 612 to the control device ECU. Accordingly, the control device ECU can acquire the temperature of the first temperature control medium TCM1 stored in the storage portion 612.

The first temperature control circuit 61 further includes a pressure control circuit 610c provided with a pressure control valve 619. An upstream end portion of the pressure control circuit 610c is connected to the storage portion 612, and a downstream end portion of the pressure control circuit 610c is connected to the pumping flow path 610a downstream of the first pump 611. The pressure control valve 619 may be a check valve or an electromagnetic valve such as a solenoid valve. When a liquid pressure of the first temperature control medium TCM1 pumped from the first pump 611 is equal to or higher than a predetermined pressure, the pressure control valve 619 is in an open state, and a part of the first temperature control medium TCM1 pumped from the first pump 611 is returned to the storage portion 612. Accordingly, the liquid pressure of the first temperature control medium TCM1 which flows through the first branch flow path 610b1 and the second branch flow path 610b2 is kept equal to or lower than the predetermined pressure.

A second pump 621, a radiator 622, and a storage tank 623 are provided in the second temperature control circuit 62. The second pump 621 is, for example, an electric pump which is driven by the electric power stored in the electric power storage device or the electric power generated by the generator 30, and which pumps the second temperature control medium TCM2. The second pump 621 is controlled by the control device ECU.

A rotational speed sensor 621a which detects a rotational speed of the second pump 621 is attached to the second pump 621. The rotational speed sensor 621a outputs a detection value of the rotational speed of the second pump 621 to the control device ECU. The control device ECU can estimate a flow rate of the second pump 621 based on the detection value of the rotational speed sensor 621a, that is, the rotational speed of the second pump 621.

The radiator 622 is disposed at a front portion of the vehicle V, and is a heat dissipation device which cools the second temperature control medium TCM2 by traveling wind during traveling of the vehicle V. The storage tank 623 is a tank which temporarily stores the second temperature control medium TCM2 which circulates in the second temperature control circuit 62. Even if cavitation occurs in the second temperature control medium TCM2 which circulates in the second temperature control circuit 62, the second temperature control medium TCM2 which circulates in the second temperature control circuit 62 is temporarily stored in the storage tank 623, so that the cavitation which occurs in the second temperature control medium TCM2 disappears.

The second temperature control circuit 62 includes a branch portion 624 and a merging portion 625. In the second temperature control circuit 62, the storage tank 623, the second pump 621, and the radiator 622 are provided in this order from an upstream side. Further, the second temperature control circuit 62 further includes a pumping flow path 620a. An upstream end portion of the pumping flow path 620a is connected to the merging portion 625, and a downstream end portion of the pumping flow path 620a is connected to the branch portion 624 through the storage tank 623, the second pump 621, and the radiator 622. The second temperature control medium TCM2 stored in the storage tank 623 passes through the pumping flow path 620a, is pumped by the second pump 621, and is cooled by the radiator 622.

The second temperature control circuit 62 further includes a first branch flow path 620b1 provided with the electric power conversion device 50, and a second branch flow path 620b2 provided in parallel with the first branch flow path 620b1 and provided with the heat exchanger 63. The first branch flow path 620b1 is an example of a first flow path of the present disclosure. The second branch flow path 620b2 is an example of a second flow path of the present disclosure.

Specifically, an upstream end portion of the first branch flow path 620b1 is connected to the branch portion 624, and a downstream end portion of the first branch flow path 620b1 is connected to the merging portion 625 through the electric power conversion device 50. An upstream end portion of the second branch flow path 620b2 is connected to the branch portion 624, and a downstream end portion of the second branch flow path 620b2 is connected to the merging portion 625 through the heat exchanger 63.

In the present embodiment, a valve device 626 serving as a flow rate adjustment valve which adjusts a flow rate of the second temperature control medium TCM2 which flows through the second branch flow path 620b2 (in other words, a flow rate of the second temperature control medium TCM2 which flows through the first branch flow path 620b1) is provided at a portion of the second branch flow path 620b2 upstream of the heat exchanger 63. In the present embodiment, it is assumed that the valve device 626 is an ON-OFF valve. That is, the valve device 626 sets the second branch flow path 620b2 in a fully opened state when the valve device 626 is opened. On the other hand, the valve device 626 sets the second branch flow path 620b2 in a fully closed state when the valve device 626 is closed. The valve device 626 is not limited to the ON-OFF valve, and may be a variable flow rate valve which can adjust the flow rate of the second temperature control medium TCM2 which flows through the second branch flow path 620b2. The valve device 626 is controlled by the control device ECU.

The second temperature control medium TCM2 pumped by the second pump 621 and cooled by the radiator 622 in the pumping flow path 620a branches into the first branch flow path 620b1 and the second branch flow path 620b2 at the branch portion 624. The second temperature control medium TCM2 which flows through the first branch flow path 620b1 cools the electric power conversion device 50, and merges with the second branch flow path 620b2 and the pumping flow path 620a at the merging portion 625. The second temperature control medium TCM2 which flows through the second branch flow path 620b2 cools the first temperature control medium TCM1 by exchanging heat with the first temperature control medium TCM1 in the heat exchanger 63, and merges with the first branch flow path 620b1 and the pumping flow path 620a at the merging portion 625. The second temperature control medium TCM2 which flows through the first branch flow path 620b1 and the second temperature control medium TCM2 which flows through the second branch flow path 620b2 merge at the merging portion 625, flow through the pumping flow path 620a, and are temporarily stored in the storage tank 623. The second temperature control medium TCM2 stored in the storage tank 623 passes through the pumping flow path 620a, is supplied to the second pump 621 again, so that the second temperature control medium TCM2 circulates in the second temperature control circuit 62.

In the present embodiment, the first branch flow path 620b1 and the second branch flow path 620b2 are formed such that the flow rate of the second temperature control medium TCM2 which flows through the first branch flow path 620b1 is higher than the flow rate of the second temperature control medium TCM2 which flows through the second branch flow path 620b2 even when the valve device 626 is opened.

A second temperature sensor 62a which detects the temperature of the second temperature control medium TCM2 which circulates in the second temperature control circuit 62 is provided in the second temperature control circuit 62. In the present embodiment, the second temperature sensor 62a is provided between the radiator 622 and the branch portion 624 of the pumping flow path 620a, detects the temperature of the second temperature control medium TCM2 discharged from the radiator 622, that is, the second temperature control medium TCM2 supplied to the electric power conversion device 50, and outputs a detection value thereof to the control device ECU. Accordingly, the control device ECU can acquire the temperature of the second temperature control medium TCM2 supplied to the electric power conversion device 50.

In the first temperature control circuit 61, when it is assumed that the temperature of the first temperature control medium TCM1 stored in the storage portion 612 after the electric motor 20, the generator 30, and the transmission device 40 are cooled is about 100[° C.], the first temperature control medium TCM1 of about 100[° C.] is supplied to the heat exchanger 63.

On the other hand, in the second temperature control circuit 62, when it is assumed that the temperature of the second temperature control medium TCM2 cooled by the radiator 622 is about 40[° C.], since the second temperature control medium TCM2 supplied to the heat exchanger 63 does not pass through the electric power conversion device 50 which is a device subjected to the temperature control, the second temperature control medium TCM2 of about 40[° C.] is supplied to the heat exchanger 63.

In this case, in the heat exchanger 63, heat is exchanged between the first temperature control medium TCM1 of about 100[° C.] and the second temperature control medium TCM2 of about 40[° C.] supplied to the heat exchanger 63. For example, the first temperature control medium TCM1 of about 80[° C.] is discharged from the heat exchanger 63 to a downstream side of the first branch flow path 610b1 of the first temperature control circuit 61, and the second temperature control medium TCM2 of about 70[° C.] is discharged from the heat exchanger 63 to a downstream side of the second branch flow path 620b2 of the second temperature control circuit 62.

In this way, since the first temperature control medium TCM1 is cooled by the heat exchanger 63, the first temperature control medium TCM1 can be cooled without separately providing a radiator for cooling the first temperature control medium TCM1 in the temperature control circuit 60. Therefore, the temperature control circuit 60 can cool the first temperature control medium TCM1 which flows through the first temperature control circuit 61 and the second temperature control medium TCM2 which flows through the second temperature control circuit 62 by using one radiator 622, so that the temperature control circuit 60 can be miniaturized.

The control device ECU is implemented by, for example, an electronic control unit (ECU) including a processor which performs various calculations, a storage device including a non-transitory storage medium which stores various pieces of information (data and programs), an input and output device which controls input and output of data between an inside and an outside of the control device ECU, and the like, and integrally controls the entire vehicle V. The control device ECU may be implemented by one ECU or may be implemented by a plurality of ECUs. The control device ECU controls, for example, the internal combustion engine ICE, the electric power conversion device 50, the second pump 621, and the valve device 626.

[Control of Second Pump and Valve Device According to Temperature Changes of Electric Motor and Electric Power Conversion Device]

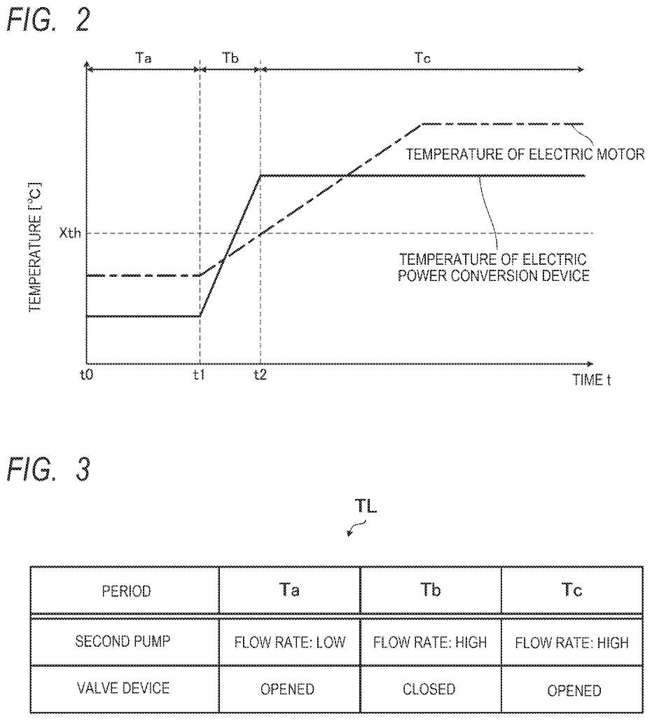

Here, an example of control of the second pump 621 and the valve device 626 according to temperature changes of the electric motor 20 and the electric power conversion device 50 performed by the control device ECU will be described with reference to FIGS. 2 and 3. FIG. 2 is a diagram illustrating an example of time changes in temperatures of the electric motor 20 and the electric power conversion device 50. In FIG. 2, a vertical axis represents a temperature [° C.], and a horizontal axis represents a time. Further, FIG. 3 is a table illustrating an example of flow rates of the second pump 621 and states of the valve device 626 respectively in periods Ta, Tb, and Tc illustrated in FIG. 2.

In FIG. 2, the period Ta from a time t0 to a time t1 is a period during which the launch control is not activated in the vehicle V, and is, for example, a period during which the vehicle V is stopped. As illustrated in a table TL in FIG. 3, the control device ECU controls the second pump 621 such that the flow rate of the second pump 621 is low and opens the valve device 626 during the period Ta (that is, when the launch control is not activated). During the period Ta, since both heat generation amounts of the electric motor 20 and the electric power conversion device 50 are small, by reducing the flow rate of the second pump 621 and opening the valve device 626, the temperatures of the electric motor 20 and the electric power conversion device 50 can be respectively kept substantially constant at temperatures lower than Xth [° C.] described later while suppressing driving of the second pump 621 to some extent.

In the present embodiment, it is assumed that when the flow rate of the second pump 621 is decreased, the control device ECU controls a rotational speed of the second pump 621 such that the flow rate of the second pump 621 is Pa [L/min]. Here, Pa is set in advance for the control device ECU by, for example, a manufacturer of the control device ECU.

During the time t1 after the time t0, it is assumed that an operation of simultaneously depressing the accelerator pedal and the brake pedal of the vehicle V is performed. Further, it is assumed that the operation of depressing the accelerator pedal at this time is, for example, an operation of fully opening a throttle of the vehicle V. When such an operation is performed, the control device ECU determines that the activation condition of the launch control has been established, and activates the launch control.

Specifically, when the activation condition of the launch control is established in this way, as compared with a case where the activation condition of the launch control is not established (for example, the period Ta), the control device ECU increases the electric power supplied to the electric motor 20 via the electric power conversion device 50 in order to increase power for driving the vehicle V. In the present embodiment, in response to the establishment of the activation condition of the launch control, the control device ECU increases the electric power supplied to the electric motor 20 via the electric power conversion device 50 by operating the internal combustion engine ICE which drives the generator 30 (that is, starting electric power generation by the generator 30).

In this way, when the electric power supplied to the electric motor 20 via the electric power conversion device 50 is increased, the heat generation amounts of the electric motor 20 and the electric power conversion device 50 increase. As a result, as illustrated in FIG. 2, from the time t1 at which the activation condition of the launch control is established, the temperatures of the electric motor 20 and the electric power conversion device 50 respectively increase. However, since the electric motor 20 and the electric power conversion device 50 have different heat capacities, increase speeds of the temperatures are also different. Specifically, since the heat capacity of the electric power conversion device 50 is smaller than that of the electric motor 20, the temperature of the electric power conversion device 50 rapidly increases and is likely to become a high temperature as compared with the electric motor 20.

Therefore, as illustrated in the table TL in FIG. 3, the control device ECU controls the second pump 621 such that the flow rate of the second pump 621 is high, and closes the valve device 626 during the period Tb from the time t1 to the time t2 (described later). Accordingly, as compared with the case where the activation condition of the launch control is not established (for example, the period Ta), an amount of the second temperature control medium TCM2 supplied to the electric power conversion device 50 per unit time can be increased. Therefore, the cooling effect of the electric power conversion device 50 by the second temperature control circuit 62 can be improved.

When the valve device 626 is closed in response to the establishment of the activation condition of the launch control, the heat exchange between the first temperature control medium TCM1 and the second temperature control medium TCM2 via the heat exchanger 63 can be prevented, and the temperature of the first temperature control medium TCM1 which circulates in the first temperature control circuit 61 can also be increased. Accordingly, the temperature of the first temperature control medium TCM1 can be rapidly increased, and an increase in friction loss of the electric motor 20 due to a low temperature of the first temperature control medium TCM1 can also be prevented.

In the present embodiment, it is assumed that when the flow rate of the second pump 621 is increased, the control device ECU controls the rotational speed of the second pump 621 such that the flow rate of the second pump 621 is Pb [L/min] (wherein Pb>Pa). Here, Pb is set in advance for the control device ECU by, for example, the manufacturer of the control device ECU.

At the time t2 after the time t1, it is assumed that the temperature of the electric motor 20 is equal to or higher than the predetermined Xth [° C.]. Here, Xth is, for example, a predetermined value set in advance for the control device ECU by the manufacturer of the control device ECU.

During the period Tc since the time t2 at which the temperature of the electric motor 20 reaches Xth [° C.] in this way, as illustrated in the table TL in FIG. 3, the control device ECU increases the flow rate of the second pump 621 (that is, sets the flow rate to Pb [L/min]), and opens the valve device 626. Accordingly, as compared with the case where the activation condition of the launch control is not established (for example, the period Ta) and a period (for example, the period Tb) before the temperature of the electric motor 20 is equal to or higher than Xth [° C.] after the activation condition of the launch control is established, the amount of the second temperature control medium TCM2 supplied to the heat exchanger 63 provided in the second branch flow path 620b2 per unit time can be increased. Therefore, the heat exchange between the first temperature control medium TCM1 and the second temperature control medium TCM2 via the heat exchanger 63 can be promoted.

In the example described above, since the activation condition of the launch control is established until the temperature of the electric motor 20 is equal to or higher than Xth [° C.], the valve device 626 is controlled such that the flow rate of the second temperature control medium TCM2 to the first branch flow path 620b1 is high (in other words, the flow rate to the second branch flow path 620b2 is low), but the present disclosure is not limited thereto. For example, since the activation condition of the launch control is established until a predetermined period elapses, the control device ECU may control the valve device 626 such that the flow rate of the second temperature control medium TCM2 to the first branch flow path 620b1 is high. Here, the predetermined period is, for example, a period set in advance for the control device ECU by the manufacturer of the control device ECU. That is, the period Tb may be a period having a length set in advance. In this way, after the predetermined period elapses since the activation condition of the launch control is established, the amount of the second temperature control medium TCM2 supplied to the heat exchanger 63 provided in the second branch flow path 620b2 per unit time can be increased. Therefore, the heat exchange between the first temperature control medium TCM1 and the second temperature control medium TCM2 via the heat exchanger 63 can be promoted.

### Process in Control Device According to First Embodiment

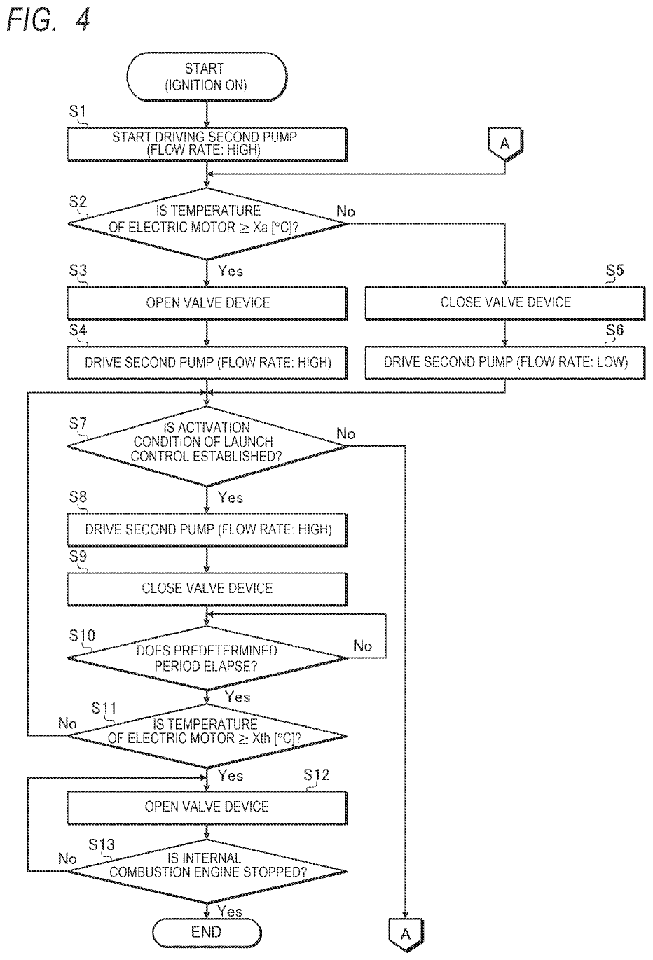

Next, an example of a process executed by the control device ECU according to the first embodiment will be described with reference to FIG. 4. For example, when the vehicle V is activated (for example, when an ignition power supply of the vehicle V is turned on), the control device ECU according to the first embodiment executes the process illustrated in FIG. 4.

As illustrated in FIG. 4, the control device ECU starts driving the second pump 621 (step S1). At this time, the control device ECU increases the flow rate of the second pump 621 (that is, sets the flow rate to Pb [L/min]).

Next, the control device ECU determines whether the temperature of the electric motor 20 is equal to or higher than predetermined Xa [° C.] (step S2). Here, Xa is a temperature higher than Xth described above, and is a temperature serving as a determination condition for determining whether cooling of the electric motor 20 is necessary. Xa is set in advance for the control device ECU by, for example, the manufacturer of the control device ECU.

When determining that the temperature of the electric motor 20 is equal to or higher than Xa [° C.] (step S2: Yes), the control device ECU opens the valve device 626 (step S3), and increases the flow rate of the second pump 621 (step S4). On the other hand, when determining that the temperature of the electric motor 20 is lower than Xa [° C.] (step S2: No), the control device ECU closes the valve device 626 (step S5), and decreases the flow rate of the second pump 621 (step S6).

Next, the control device ECU determines whether the activation condition of the launch control is established (step S7). When determining that the activation condition of the 5 launch control is not established (step S7: No), the control device ECU returns to the process of step S2.

On the other hand, when determining that the activation condition of the launch control is established (step S7: Yes), the control device ECU proceeds to a process of step S8. At this time, for example, the control device ECU determines whether the internal combustion engine ICE operates. When the internal combustion engine ICE does not operate, the control device ECU causes the internal combustion engine ICE to operate, and then proceeds to the process of step S8.

Next, the control device ECU increases the flow rate of the second pump 621 (step S8) and closes the valve device 626 (step S9). At this time, the control device ECU may further perform the processes of step S8 and step S9 on the condition that the temperature of the electric power conversion device 50 or the second temperature control medium TCM2 is equal to or higher than a predetermined value.

Next, the control device ECU waits until a predetermined period during which a response delay of the second pump 621 for the process of step S8 or a response delay of the valve device 626 for the process of step S9 is considered elapses (step S10: a loop of No).

When the predetermined period elapses (step S10: Yes), the control device ECU determines whether the temperature of the electric motor 20 is equal to or higher than Xth [° C.] (step S11).

When determining that the temperature of the electric motor 20 is lower than Xth [° C.] (step S11: No), the control device ECU returns to the process of step S7. On the other hand, when determining that the temperature of the electric motor 20 is equal to or higher than Xth [° C.] (step S11: Yes), the control device ECU opens the valve device 626 (step S12).

Next, the control device ECU determines whether the internal combustion engine ICE is stopped (step S13). For example, in a case where the internal combustion engine ICE is operated in response to the establishment of the activation condition of the launch control, the control device ECU stops the internal combustion engine ICE when the launch control is ended by, for example, weakening a depression operation on the accelerator pedal of the vehicle V thereafter.

When determining that the internal combustion engine ICE is not stopped, that is, the internal combustion engine ICE operates (step S13: No), the control device ECU maintains a state where the valve device 626 is opened. Since the state where the valve device 626 is opened is maintained in this way, it is possible to prevent unnecessary opening and closing of the valve device 626, and to prevent deterioration of the valve device 626. On the other hand, when determining that the internal combustion engine ICE is stopped (step S13: Yes), for example, the control device ECU returns to normal control (not illustrated), and ends the series of processes illustrated in FIG. 4.

As described above, when the activation condition of the launch control is established, the control device ECU controls the second pump 621 such that the flow rate of the second pump 621 is high as compared with the case where the activation condition of the launch control is not established. Accordingly, when the activation condition of the launch control is established, the amount of the second temperature control medium TCM2 supplied to the electric power conversion device 50 per unit time can be increased, and the cooling effect of the electric power conversion device 50 by the second temperature control circuit 62 can be improved, as compared with the case where the activation condition of the launch control is not established. Therefore, the electric power conversion device 50 which is likely to generate heat due to the activation of the launch control can be appropriately cooled.

On the other hand, when the activation condition of the launch control is not established, that is, when the heat generation amount of the electric power conversion device 50 is small, the control device ECU can reduce energy (for example, electric power consumption of the second pump 621) for driving the second pump 621 and reduce a driving sound of the second pump 621 by decreasing the flow rate of the second pump 621.

Since the control device ECU increases the flow rate of the second pump 621, for example, at a time point at which the activation condition of the launch control is established, it is possible to improve the cooling effect of the electric power conversion device 50 by the second temperature control circuit 62 at an early stage as compared with a case where the flow rate of the second pump 621 is high after the temperature of the electric power conversion device 50 is equal to or higher than the predetermined value. Therefore, the electric power conversion device 50 which is likely to generate heat due to the activation of the launch control can be appropriately cooled.

When the activation condition of the launch control is established, the control device ECU controls the valve device 626 such that the flow rate of the second temperature control medium TCM2 to the first branch flow path 620b1 provided with the electric power conversion device 50 is high (in other words, the flow rate of the second temperature control medium TCM2 to the second branch flow path 620b2 provided in parallel with the first branch flow path 620b1 is low) as compared with the case where the activation condition of the launch control is not established. Accordingly, the amount of the second temperature control medium TCM2 supplied to the electric power conversion device 50 per unit time can be increased, and the cooling effect of the electric power conversion device 50 by the second temperature control circuit 62 can be improved.

Since the heat exchanger 63 is provided in the second branch flow path 620b2, the heat exchange between the first temperature control medium TCM1 and the second temperature control medium TCM2 via the heat exchanger 63 can be prevented by decreasing the flow rate of the second temperature control medium TCM2 to the second branch flow path 620b2 in response to the establishment of the activation condition of the launch control. Accordingly, it is possible to prevent heat of the first temperature control medium TCM1 (that is, the electric motor 20) from being transferred to the second temperature control medium TCM2, and to improve the cooling effect of the electric power conversion device 50 by the second temperature control circuit 62.

### Second Embodiment

Next, a second embodiment of the present disclosure will be described. In the following description, parts different from those of the first embodiment will be mainly described, and illustration and description of parts common to those of the first embodiment will be omitted or simplified as appropriate.

### Vehicle According to Second Embodiment

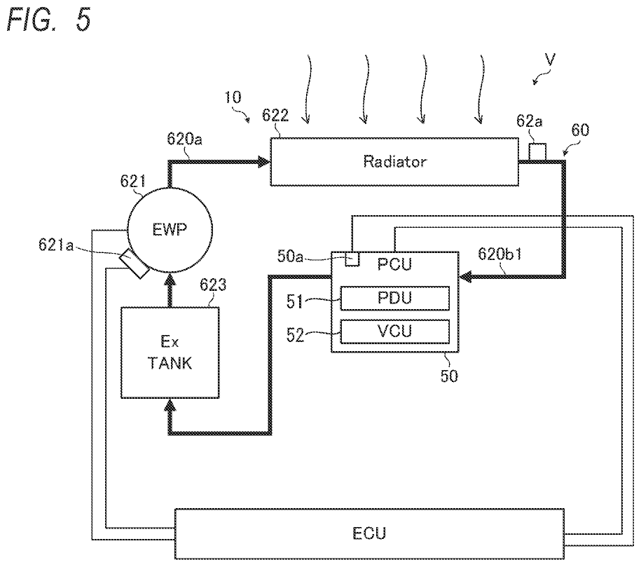

As illustrated in FIG. 5, a vehicle V according to the second embodiment is different from the vehicle V according to the first embodiment in that the second branch flow path 620b2, the valve device 626, and the heat exchanger 63 are eliminated. Although illustration and detailed description are omitted, for example, in the vehicle V according to the second embodiment, a radiator (not illustrated) serving as a heat dissipation device which cools the first temperature control medium TCM1 which circulates in the first temperature control circuit 61 is provided in the first temperature control circuit 61 (not illustrated) separately from the radiator 622 of the second temperature control circuit 62.

### Process in Control Device According to Second Embodiment

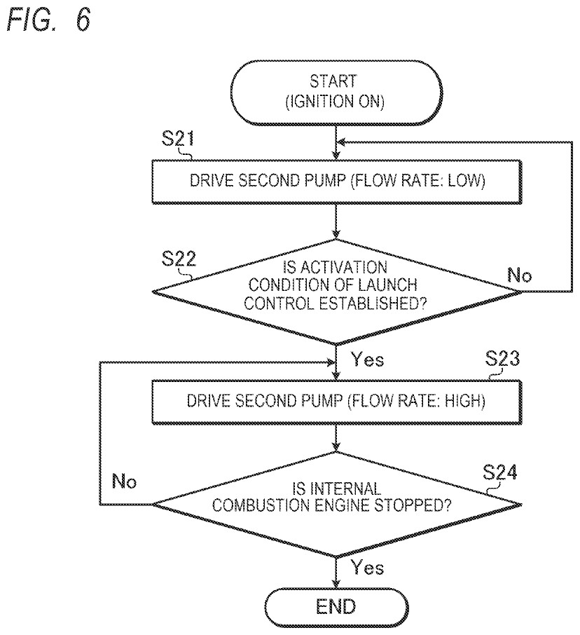

Next, an example of a process executed by a control device ECU according to the second embodiment will be described with reference to FIG. 6. For example, when the vehicle V is activated (for example, when an ignition power supply of the vehicle V is turned on), the control device ECU according to the second embodiment executes the process illustrated in FIG. 6.

As illustrated in FIG. 6, the control device ECU starts driving the second pump 621 (step S21). At this time, the control device ECU decreases a flow rate of the second pump 621.

Next, the control device ECU determines whether an activation condition of launch control is established (step S22). When determining that the activation condition of the launch control is not established (step S22: No), the control device ECU returns to the process of step S21. On the other hand, when determining that the activation condition of the launch control is established (step S22: Yes), the control device ECU increases the flow rate of the second pump 621 (step S23).

Next, the control device ECU determines whether the internal combustion engine ICE is stopped (step S24). When determining that the internal combustion engine ICE is not stopped, that is, the internal combustion engine ICE operates (step S24: No), the control device ECU maintains a state where the flow rate of the second pump 621 is increased. When the internal combustion engine ICE operates, a driving sound of the second pump 621 is difficult for the user to understand due to a driving sound (operation sound) of the internal combustion engine ICE. Therefore, when the internal combustion engine ICE operates, for example, when the launch control is activated, even if the second pump 621 is driven in a state where the flow rate of the second pump 621 is high (in other words, in a high load state), it is possible to avoid deterioration of noise and vibration (NV) performance of the vehicle V due to the driving sound of the second pump 621.

When determining that the internal combustion engine ICE is stopped (step S24: Yes), for example, the control device ECU returns to normal control (not illustrated), and ends the series of processes illustrated in FIG. 6.

As described above, when the activation condition of the launch control is established, the control device ECU according to the second embodiment controls the second pump 621 such that the flow rate of the second pump 621 is high as compared with a case where the activation condition of the launch control is not established. Accordingly, similar to the first embodiment, when the activation condition of the launch control is established, an amount of the second temperature control medium TCM2 supplied to the electric power conversion device 50 per unit time can be increased, and a cooling effect of the electric power conversion device 50 by the second temperature control circuit 62 can be improved, as compared with the case where the activation condition of the launch control is not established. Therefore, the electric power conversion device 50 which is likely to generate heat due to the activation of the launch control can be appropriately cooled.

Although the embodiments of the present invention have been described above with reference to the accompanying drawings, it goes without saying that the present invention is not limited to such an embodiment. It will be apparent to those skilled in the art that various changes and modifications may be conceived within the scope of the claims. It is also understood that the various changes and modifications belong to the technical scope of the present invention. Further, constituent elements in the embodiments described above may be combined freely within a range not departing from a spirit of the invention.

For example, in the embodiment described above, the configuration in which the electric power conversion device 50 and the heat exchanger 63 are disposed in parallel with each other has been described, but a configuration in which the electric power conversion device 50 and the heat exchanger 63 are disposed in series may be used. In this case, for example, the configuration in which the electric power conversion device 50 is disposed between the radiator 622 and the branch portion 624 illustrated in FIG. 1 may be used.

In the present specification, at least the following matters are described. Constituent elements and the like corresponding to those according to the embodiments described above are shown in parentheses. However, the present invention is not limited thereto.

(1) A vehicle (the vehicle V) for activating launch control in response to establishment of a predetermined activation condition, the vehicle (the vehicle V) including:

an electric power conversion device (the electric power conversion device 50) configured to control electric power supplied to an electric motor (the electric motor 20);

the electric motor configured to drive a driven wheel according to electric power supplied via the electric power conversion device;

a temperature control circuit (the second temperature control circuit 62) in which a temperature control medium (the second temperature control medium TCM2) circulates to control a temperature of the electric power conversion device; and

a control device (the control device ECU), in which:

the temperature control circuit includes a pump (the second pump 621) configured to pump the temperature control medium; and

the control device is configured to control the pump, and when the activation condition is established, the control device is configured to control the pump such that a flow rate of the pump is high as compared with a case where the activation condition is not established.

According to (1), when the activation condition of the launch control is established, the pump can be controlled such that the flow rate of the pump of the temperature control circuit which controls the temperature of the electric power conversion device is high as compared with the case where the activation condition of the launch control is not established.

Accordingly, when the activation condition of the launch control is established, an amount of the temperature control medium supplied to the electric power conversion device per unit time can be increased, and a cooling effect of the electric power conversion device by the temperature control circuit can be improved, as compared with the case where the activation condition of the launch control is not established. Therefore, the electric power conversion device which is likely to generate heat due to the activation of the launch control can be appropriately cooled.

(2) The vehicle according to (1), in which:

the temperature control circuit further includes:
a first flow path (the first branch flow path 620b1) provided with the electric power conversion device;
a second flow path (the second branch flow path 620b2) provided in parallel with the first flow path: and
a flow rate adjustment valve (the valve device 626) configured to adjust a flow rate of the temperature control medium to the second flow path: and

the control device is configured to control the flow rate adjustment valve, and when the activation condition is established, the control device is configured to control the flow rate adjustment valve such that a flow rate to the first flow path is high as compared with the case where the activation condition is not established.

According to (2), when the activation condition of the launch control is established, the flow rate adjustment valve can be controlled such that the flow rate of the temperature control medium to the first flow path provided with the electric power conversion device is high (in other words, the flow rate of the temperature control medium to the second flow path provided in parallel with the first flow path is low) as compared with the case where the activation condition of the launch control is not established. Accordingly, when the activation condition of the launch control is established, an amount of the temperature control medium supplied to the electric power conversion device per unit time can be increased, and a cooling effect of the electric power conversion device by the temperature control circuit can be improved, as compared with the case where the activation condition of the launch control is not established.

(3) The vehicle according to (2), further including:

a first temperature control circuit (the second temperature control circuit 62) serving as the temperature control circuit in which a first temperature control medium (the second temperature control medium TCM2) which is the temperature control medium circulates;

a second temperature control circuit (the first temperature control circuit 61) in which a second temperature control medium (the first temperature control medium TCM1) circulates to control a temperature of the electric motor; and

a heat exchanger (the heat exchanger 63) configured to perform heat exchange between the first temperature control medium configured to circulate in the first temperature control circuit and the second temperature control medium configured to circulate in the second temperature control circuit, in which

the heat exchanger is provided in the second flow path.

According to (3), the heat exchanger which performs the heat exchange between the first temperature control medium which circulates in the first temperature control circuit which controls the temperature of the electric power conversion device and the second temperature control medium which circulates in the second temperature control circuit which controls the temperature of the electric motor is provided in the second flow path. Therefore, by decreasing the flow rate of the first temperature control medium to the second flow path in response to the establishment of the activation condition of the launch control, it is possible to prevent the heat exchange between the first temperature control medium and the second temperature control medium via the heat exchanger. Accordingly, it is possible to prevent heat of the second temperature control medium (that is, the electric motor) from being transferred to the first temperature control medium to improve the cooling effect of the electric power conversion device by the first temperature control circuit.

(4) The vehicle according to (3), in which

when the activation condition is established, the control device is configured to control the flow rate adjustment valve such that a flow rate to the first flow path is high since the activation condition is established until a predetermined period elapses.

According to (4), since the activation condition of the launch control is established after the predetermined period elapses, an amount of the first temperature control medium supplied to the heat exchanger provided in the second flow path provided in parallel with the first flow path per unit time can be increased. Therefore, the heat exchange between the first temperature control medium and the second temperature control medium via the heat exchanger can be promoted.

(5) The vehicle according to (3), in which

the control device is configured to acquire a temperature of the electric motor, and when the activation condition is established, the control device is configured to control the flow rate adjustment valve such that a flow rate to the first flow path is high since the activation condition is established until the temperature of the electric motor is equal to or higher than a predetermined value (Xth [° C.]).

According to (5), since the activation condition of the launch control is established and after the temperature of the electric motor is equal to or higher than the predetermined value, the amount of the first temperature control medium supplied to the heat exchanger provided in the second flow path provided in parallel with the first flow path per unit time can be increased.

Therefore, the heat exchange between the first temperature control medium and the second temperature control medium via the heat exchanger can be promoted.

(6) The vehicle according to any one of (1) to (5), in which

the vehicle further includes an internal combustion engine (the internal combustion engine ICE), and causes the internal combustion engine to operate in response to establishment of the activation condition.

According to (6), it is possible to avoid deterioration of noise and vibration (NV) performance of the vehicle due to a driving sound of the pump.

(7) The vehicle according to any one of (1) to (6), in which

the activation condition is an operation of simultaneously depressing an accelerator pedal and a brake pedal of the vehicle.

According to (7), the launch control can be activated in response to a request (operation) from a user of the vehicle, and the activation of the launch control against an intention of the user can be avoided.

What is claimed is:

1. A vehicle for activating launch control in response to establishment of a predetermined activation condition, the vehicle comprising:
an electric power conversion device configured to control electric power supplied to an electric motor;
the electric motor configured to drive a driven wheel according to electric power supplied via the electric power conversion device;
a temperature control circuit in which a temperature control medium circulates to control a temperature of the electric power conversion device; and
a control device, wherein:
the temperature control circuit includes a pump configured to pump the temperature control medium; and
the control device is configured to control the pump, and when the activation condition is established, the control device is configured to control the pump such that a flow rate of the pump is high as compared with a case where the activation condition is not established.

2. The vehicle according to claim 1, wherein:
the temperature control circuit further includes:
a first flow path provided with the electric power conversion device;
a second flow path provided in parallel with the first flow path; and
a flow rate adjustment valve configured to adjust a flow rate of the temperature control medium to the second flow path; and
the control device is configured to control the flow rate adjustment valve, and when the activation condition is established, the control device is configured to control the flow rate adjustment valve such that a flow rate to the first flow path is high as compared with the case where the activation condition is not established.

3. The vehicle according to claim 2, further comprising:
a first temperature control circuit serving as the temperature control circuit in which a first temperature control medium which is the temperature control medium circulates;
a second temperature control circuit in which a second temperature control medium circulates to control a temperature of the electric motor; and
a heat exchanger configured to perform heat exchange between the first temperature control medium configured to circulate in the first temperature control circuit and the second temperature control medium configured to circulate in the second temperature control circuit, wherein
the heat exchanger is provided in the second flow path.

4. The vehicle according to claim 3, wherein
when the activation condition is established, the control device is configured to control the flow rate adjustment valve such that a flow rate to the first flow path is high since the activation condition is established until a predetermined period elapses.

5. The vehicle according to claim 3, wherein
the control device is configured to acquire a temperature of the electric motor, and when the activation condition is established, the control device is configured to control the flow rate adjustment valve such that a flow rate to the first flow path is high since the activation condition is established until the temperature of the electric motor is equal to or higher than a predetermined value.

6. The vehicle according to claim 1, wherein
the vehicle further includes an internal combustion engine, and causes the internal combustion engine to operate in response to establishment of the activation condition.

7. The vehicle according to claim 1, wherein
the activation condition is an operation of simultaneously depressing an accelerator pedal and a brake pedal of the vehicle.
